(19) United States
(12) Patent Application Publication
(10) Pub. No.: US 2005/0212534 A1
(43) Pub. Date: Sep. 29, 2005

(54) Method and apparatus for monitoring corrosion

(76) Inventor: Robert Alan Cottis, Stockport (GB)

Correspondence Address: WOODARD, EMHARDT, MORIARTY, MCNETT & HENRY LLP, BANK ONE CENTER/TOWER, 111 MONUMENT CIRCLE, SUITE 3700, INDIANAPOLIS, IN, 46204-5137, US

(21) Appl. No.: 10/518,662

(22) PCT Filed: Jun. 6, 2003
(86) PCT No.: PCT/GB03/02445

§ 371 Date: Dec. 17, 2004

(30) Foreign Application Priority Data
Jun. 17, 2002 (GB) 0213912.9

(51) Int. Cl. G01R 27/08; G01N 27/00

(52) U.S. Cl. 324/700; 324/71.2

(57) ABSTRACT

A method and apparatus for monitoring the corrosion of a working electrode. An alternating perturbation signal of at least one frequency is applied to the working electrode. A signal representing the response of the working electrode to the applied perturbation signal is monitored. The monitored signal is filtered to separate out a signal representing the response of the electrode to the or each applied frequency and an electrochemical noise output signal representative of corrosion of the working electrode. The potential of the working electrode relative to a reference electrode may be controlled by controlling the supply of current through an auxiliary electrode. The supplied current is then monitored and the monitored current is filtered. Alternatively, a known alternating current may be applied between the working electrode and an auxiliary electrode and fluctuations in the potential of the working electrode relative to a reference electrode may be monitored, the monitored potential being filtered. A measure of the impedance of the working electrode is derived from the applied perturbation signal and the response signal. Both electrochemical potential noise and electrochemical current noise measurements may be derived from the known applied potential and the measured current or the known applied current and the monitored potential.

The present invention relates to a method and apparatus for monitoring the corrosion of a working electrode.

The measurement of electrochemical impedance has been demonstrated to provide useful information about corrosion processes. In particular, a measurement of electrochemical impedance can indicate the rate of corrosion and the presence and characteristics of surface films on a working electrode. Electrochemical impedance measurements are useful when monitoring uniform corrosion conditions but are typically rather poor at detecting localised corrosion such as pitting, stress corrosion, cracking or crevice attack.

In greater detail, the low frequency impedance of a corroding electrode is known to provide information about the rate of corrosion of the electrode in accordance with the Stern-Geary equation:

$${i}_{corr} = \frac{B}{{R}_{P}} \qquad ( 1 )$$

where i_{corr} is the corrosion current density (the corrosion rate expressed as a current per unit area), Rₚ is the polarization resistance (the impedance of the electrode measured at a low frequency) and B is the Stern-Geary coefficient (which will be a constant for a given corrosion system).

The above analysis only allows for the calculation of a rate of corrosion expressed as a uniform attack (whether or not the attack is actually uniform). In contrast, the fluctuations of the electrochemical potential or current associated with the corrosion process (known as electrochemical noise) indicate the tendency for localization of the corrosion. If the corrosion is assumed to occur as a series of rapid ‘events’, each causing the loss of a fixed amount of metal, and potential noise is measured, it is known that the frequency of the events (fₙ) is proportional to the low frequency power spectral density of the potential according to:

$${f}_{n} = \frac{{B}^{2}}{{ψ}_{E}} \qquad ( 2 )$$

where B is the Stern-Geary coefficient as above, and ψ_{E} is the power spectral density of potential. If the current noise is measured, then the above equation is modified by using Ohm's Law to calculate the potential noise:

$${f}_{n} = \frac{{B}^{2}}{{ψ}_{I} {R}_{P}^{2}} \qquad ( 3 )$$
where ψ_{I} is the low frequency power spectral density of current.

If fₙ is low, then the corrosion process is occurring as a few large amplitude events, which implies that it is probably localised, while a high value of fₙ implies that there are many small events, and the corrosion is expected to be uniform. A value in the range of 100-1000 Hz for 1 cm² electrode is generally thought to be a reasonable boundary between low and high values of fₙ, although the value will depend upon the corrosion system.

Electrochemical noise measurements typically record the electrochemical current noise (ECN), that is the fluctuation in the current between two nominally identical electrodes, and the electrochemical potential noise (EPN), that is the fluctuation in potential of the current-measuring pair of electrodes with respect to a reference electrode. It has been shown that the measurement of both ECN and EPN permits the estimation of both corrosion rate (using the electrochemical noise resistance or impedance in place of Rp in equation (1) above) and the tendency to localisation of corrosion (using a variety of parameters, including the characteristic charge and characteristic frequency). However, the analysis of electrochemical noise data in this way is only feasible when the two current measuring electrodes have the same characteristic behaviour. Unfortunately this is often not the case, and the general analysis of the behaviour of asymmetrical pairs of electrodes is difficult, as only two fundamental parameters can be measured (potential and current) whereas there are four unknowns (the impedance and the current noise associated with each of the two electrodes).

A known method and apparatus for detecting and measuring localised corrosion of a metallic surface of the type discussed in general terms above is described in detail in U.S. Pat. No. 5,139,627. The described method does however require the monitoring of signals generated between an array of at least three electrodes and thus is vulnerable to the problems discussed above with regard to asymmetrical electrodes.

It is an objective of the present invention to provide an improved method and apparatus for monitoring the corrosion of a working electrode which obviates or mitigates the problems outlined above.

According to the present invention, there is provided a method for monitoring corrosion of a working electrode, wherein an alternating perturbation signal of at least one frequency is applied to the working electrode, a signal representing the response of the working electrode to the applied perturbation signal is monitored, and the monitored signal is filtered to separate out a signal representing the response of the electrode to the or each applied frequency and an electrochemical noise output signal representative of corrosion at the working electrode.

A measure of impedance may be derived from the applied perturbation signal and the response signal and a further electrochemical noise signal may be derived from the impedance and the monitored signal. Thus both EPN and ECN measurements may be made utilising only one working electrode.

In one arrangement, an alternating potential control signal is generated, the potential between the working electrode and a reference electrode exposed to the same environment as the working electrode is monitored, an alternating perturbation current signal is applied through an auxiliary electrode which is exposed to the same environment as the working electrode such that the monitored potential is the same as the potential of the control signal, the applied current signal is monitored, the monitored current is filtered to separate out a signal representing the response of the electrode to the or each applied frequency and a signal which represents electrochemical current noise, a measure of the impedance of the working electrode is derived from the applied current signal and the response signal, and a signal representing electrochemical potential noise is derived from the filtered signal and the derived impedance measure.

In another arrangement, an alternating current perturbation signal is applied between the working electrode and an auxiliary electrode which is exposed to the same environment as the working electrode, the potential between the working electrode and a reference electrode which is exposed to the same environment as the working electrode is monitored, the monitored potential is filtered to separate out a signal representing the response of the electrode to the or each applied frequency and a signal which represents electrochemical potential noise, a measure of the impedance of the working electrode is derived from the applied perturbation signal and the response signal, a signal representing electrochemical current noise is derived from the filtered signal and the derived impedance measure.

The alternating perturbation signal may have a DC offset and may comprise one or more sinewaves. The pertubating signal may contain sinewaves that have a period that has integral multiple relationships to a frequency at which the electrochemical noise signal is sampled by the measurement system.

The present invention also provides an apparatus for performing the method outlined above.

An embodiment of the present invention will now be described, by way of example, with reference to the accompanying drawings, in which:

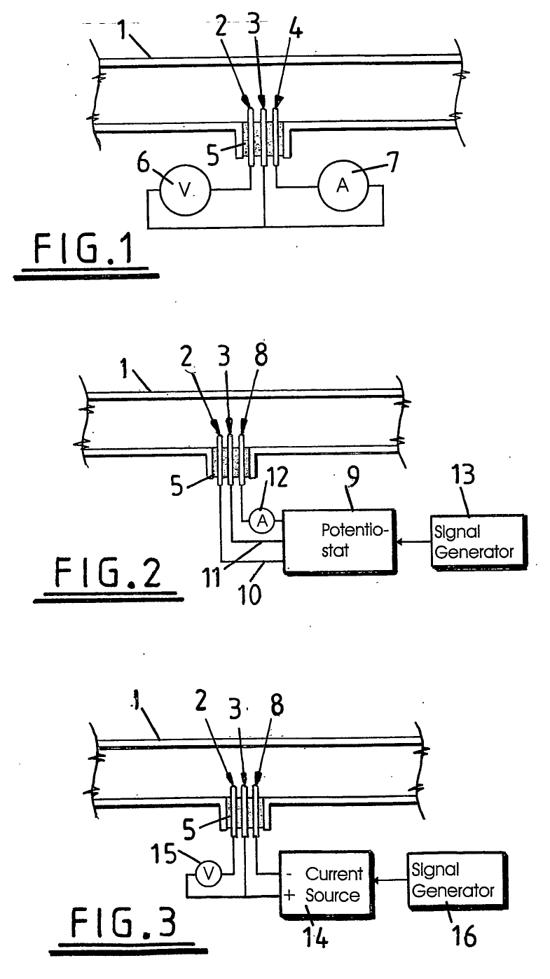

FIG. 1 is a schematic representation of a conventional electrochemical noise measurement system;

FIG. 2 is a schematic representation of a first embodiment of the present invention;

FIG. 3 is a schematic representation of a second embodiment of the present invention;

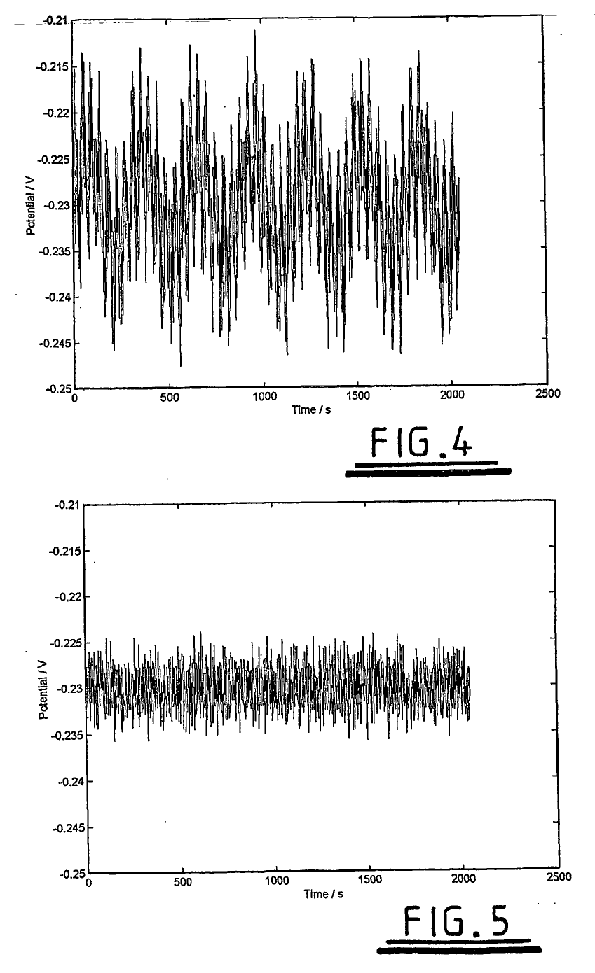

FIG. 4 is a graphical representation of a noise signal combined with three sinewaves;

FIG. 5 is a graphical representation of the noise signal shown in FIG. 4 before the combination with that signal of three sinewaves;

FIG. 6 is a graphical representation of the power spectrum of the signal of FIG. 4; and

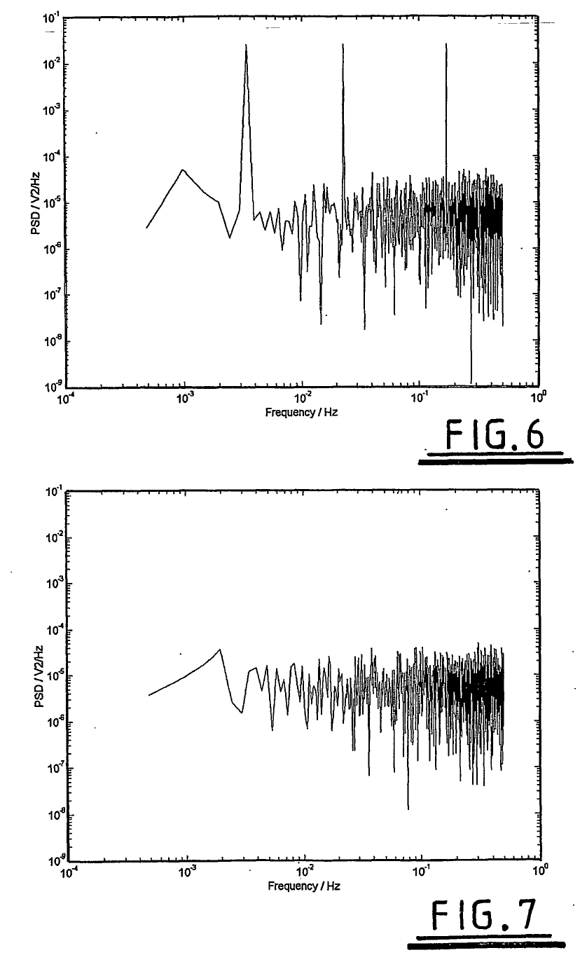

FIG. 7 is a graphical representation of the power spectrum of the signal of FIG. 5.

Referring to FIG. 1, a pipeline 1 has an array of three electrodes 2, 3 and 4 embedded in a seal 5. Electrode 2 is a reference electrode and is fabricated either from a chemically inert material which will not corrode in the environment which it is expected will be established within the pipeline 1, or from the same metal as the pipeline 1. The electrodes 3 and 4 are working electrodes and are fabricated from the same metal as the pipeline 1. A voltmeter 6 is connected between electrodes 2 and 3 and an ammeter 7 is connected between electrodes 3 and 4.

No external potentials are applied to any of the electrodes 2, 3 and 4 and thus all the signals which are detected by the voltmeter 6 and ammeter 7 are the result of electrochemical noise. The electrochemical potential noise (EPN) is measured as the fluctuation in potential between the reference electrode 2 and the working electrode 3. The ammeter 7 measures current noise flowing between the two electrodes 3 and 4 and thus outputs a signal corresponding to the electrochemical current noise (ECN). The electrodes 3 and 4 are nominally identical and, providing that this is the case, it has been shown that the measurements of ECN and EPN delivered by the ammeter 7 and voltmeter 6 permit the estimation of both corrosion rate (using the electrochemical noise resistance or impedance) and corrosion type (using a variety of parameters, including the characteristic charge and characteristic frequency). Unfortunately in practice the behaviour of the electrodes 3 and 4 is often asymmetrical and therefore reliable measurements of ECN and EPN are not possible.

Referring to FIG. 2, a first embodiment of the present invention will now be described. The same reference numerals are used in FIG. 2 as in FIG. 1 where appropriate. As in the case of the conventional arrangement of FIG. 1, three electrodes are embedded in a seal 5 in the wall of pipeline 1. In this example a first reference electrode 2 is fabricated from an inert material whereas a second working electrode 3 is fabricated from the same material as the pipeline. The third electrode 8 however is not a second working electrode but rather is an auxiliary electrode manufactured from an inert material. In other examples all three electrodes would be made from the same material as the pipe.

A potentiostat 9 is connected directly to the reference and working electrodes via connections 10 and 11 respectively and via an ammeter 12 to the auxiliary electrode 8. The potentiostat is responsive to the output of a signal generator 13, the output of the signal generator consisting of a DC component onto which an alternating component consisting of one or more sinewaves has been superimposed. The potentiostat 9 operates so as to supply current through the ammeter 12 to the auxiliary electrode 8 such that the potential between the reference electrode 2 and the working electrode 3 (which is the potential between connections 10 and 11) is the same as the control signal delivered at the output of the signal generator 13. The current measured by the ammeter will therefore be an alternating current upon which a noise signal resulting from corrosion of the working electrode 3 is superimposed.

Thus the working electrode 3 is held at a fixed mean potential with a small superimposed AC potential fluctuation. The fixed mean potential may be selected so as to offset any difference in potential between the working electrode 3 and the reference electrode 2, or it may provide a deliberate voltage offset. Generally the mean potential will normally be the corrosion potential, although other mean potentials may also be used to modify the sensitivity of the working electrode 3 to pitting, crevice corrosion, stress-corrosion cracking or other phenomena.

The current as measured by ammeter 12 will include components at the frequency or frequencies of the AC potential fluctuation. Current as measured may be separated into a component at that frequency or frequencies and a signal which is representative of electrochemical current noise. Given that the applied potential fluctuation is also known, the impedance of the working electrode at the or each applied frequency can be calculated from the known potential fluctuation and the known current fluctuation at the or each frequency by dividing the voltage fluctuation by the current fluctuation. The calculated impedance can be used in the above standard equations. Thus both ECN and EPN can be measured using a single working electrode.

Referring now to FIG. 3, an alternative embodiment of the invention will be described which relies upon measurement of voltage with a controlled current in contrast to the approach adopted in FIG. 2 which relies upon measurement of current with a controlled potential. The same reference numerals are used in FIG. 3 as in FIG. 2 where appropriate. Thus once again there is a reference electrode 2, a working electrode 3 and an auxiliary electrode 8.

A current source 14 is connected between the working electrode 3 and the auxiliary electrode 8 and a voltmeter 15 is connected to monitor the potential between the reference electrode 2 and the working electrode 3. A signal generator 16 provides an output which controls the magnitude of the current delivered by the current source 14. The output of the signal generator 16 is a sinewave which causes the current source to deliver a sinewave current perturbation to the working electrode 3. Resultant fluctuations in the potential of the working electrode are monitored by the voltmeter 15. Generally the current produced by the current source 14 will be proportional to the output of the signal generator 16. The signal generator output may consist of more than one sinewave, with an additional DC offset where it is desired to apply a non-zero mean current. The use of a non-zero mean current may be valuable in corrosion monitoring situations where a mean anodic current will enhance the sensitivity to pitting and crevice corrosion.

The potential measured by the voltmeter 15 will comprise components at the or each of the sinewave frequencies of the applied current with a superimposed noise signal. Filtering out the or each sinewave frequency leaves a signal which corresponds to the electrochemical potential noise. The impedance of the working electrode 3 can be calculated from the known applied current fluctuations and the measured voltage fluctuations as above. Again both ECN and EPN can be determined using a single working electrode.

FIG. 4 shows a potential noise signal with three superimposed sinewaves having frequencies of 7/2048, 47/2048 and 349/2048 such that there are 7, 47 and 349 cycles in a 2048 second sample period. FIG. 5 shows the noise signal of FIG. 4 without the applied sinewaves. Thus in the embodiment of the invention described in FIG. 3, the output of the voltmeter 15 would correspond to the signal represented in FIG. 4, whereas that signal after filtering to remove the three sinewave components is represented in FIG. 5.

FIG. 6 represents the power spectrum of the signal shown in FIG. 4 whereas FIG. 7 shows the power spectrum of the signal of FIG. 5. Thus it can be seen that the application of the three low amplitude sinewave signals (in this illustrated case applied at a relatively high level as compared with the underlying noise signal) has very little effect on the general shape or level of the spectrum, but the amplitude of the sinewave signals can easily be extracted from the power spectrum.

In the embodiment of the invention illustrated in FIG. 2 it is assumed that the potential of the working electrode 3 relative to the reference electrode 2 is the same as the control signal delivered by the signal generator 13. In some electronic configurations the potential applied to the working electrode may be equal to minus the control signal, and there may be other variations in the control system and the measurement of the current. Such variations will be familiar to those skilled in the field of corrosion monitoring circuitry and electrochemistry.

Although in the embodiments of the invention illustrated in FIGS. 2 and 3 separate signal generators, potentiostats or current sources and ammeters or voltmeters are illustrated, in practical systems these components will typically be incorporated in a computerised system that will perform voltage and current monitoring as well as providing the function of the signal generator.

Reference has been made to the perturbation signals incorporating one or more sinewaves and to filtering out the applied sinewave components from the monitored signal. It will be appreciated that alternating perturbations which are not based on one or more sinewaves may be used although sinewaves are preferred as this makes it possible to use a Fourier Transform of a digitised time record to achieve the necessary filtering. This approach is particularly effective if the time record includes an integral number of cycles of the sinewave, as this avoids leakage of power to adjacent frequency “bins” of the filter, and thereby results in a very clean separation of the sinewave and noise components. Using this approach it is feasible to apply several sinewaves simultaneously. The frequency of the applied perturbation may be varied from time to time to permit the determination of impedance spectra over a range of frequencies. Harmonics of the applied perturbation may also be filtered out if necessary, and these may also be analysed to extract useful information about the corrosion process using known methods of harmonic analysis.

1. A method for monitoring corrosion of a working electrode, wherein an alternating perturbation signal of at least one frequency is applied to the working electrode, a signal representing the response of the working electrode to the applied perturbation signal is monitored, and the monitored signal is filtered to separate out a signal representing the response of the electrode to the or each applied frequency and an electrochemical noise output signal representative of corrosion at the working electrode.

2. A method according to claim 1, wherein a measure of impedance is derived from the applied perturbation signal and the response signal, and a further electrochemical noise signal is derived from the impedance and the said output signal.

3. A method according to claim 2, wherein the said output signal represents electrochemical current noise and the said further electrochemical noise signal represents electrochemical potential noise.

4. A method according to claim 2, wherein the said output signal represents electrochemical potential noise and the said further electrochemical noise signal represents electrochemical current noise.

5. A method according to claim 3, wherein an alternating potential control signal is generated, the potential between the working electrode and a reference electrode exposed to the same environment as the working electrode is monitored, an alternating perturbation current signal is applied through an auxiliary electrode which is exposed to the same environment as the working electrode such that the monitored potential is the same as the potential of the control signal, the applied current is monitored, the monitored current is filtered to separate out a signal representing the response of the electrode to the or each applied frequency and a signal which represents the electrochemical current noise, a measure of the impedance of the working electrode is derived from the applied current signal and the response signal, an-d a signal representing electrochemical potential noise is derived from the filtered signal and the derived impedance measure.

6. A method according to claim 4, wherein an alternating current perturbation signal is generated, an alternating current is applied between the working electrode and an auxiliary electrode which is exposed to the same environment as the working electrode, the potential between the working electrode and a reference electrode which is exposed to the same environment as the working electrode is monitored, the monitored potential is filtered to separate out a signal representing the response of the electrode to the or each applied frequency and a signal which represents electrochemical current noise, a measure of the impedance of the working electrode is derived from the applied perturbation signal and the response signal, and a signal representing electrochemical current noise is derived from the filtered signal and the derived impedance measure.

7. A method according to claim 1 wherein the alternating perturbation signal has a DC offset.

8. A method according to claim 1 wherein the alternating perturbation signal comprises one or more sinewaves.

9. A method according to claim 8, wherein the perturbating signal contains sinewaves that have a period that has an integral multiple relationship to a frequency at which the electrochemical noise signal is sampled.

10. An apparatus for performing the method according to claim 1.

11. (canceled)
